(19) United States
(12) Patent Application Publication
(10) Pub. No.: US 2013/0206592 A1
(43) Pub. Date: Aug. 15, 2013

(54) Ferromagnetic Sputtering Target

(71) Applicants: Atsutoshi Arakawa, Ibaraki (JP); Yuki Ikeda, Ibaraki (JP)

(72) Inventors: Atsutoshi Arakawa, Ibaraki (JP); Yuki Ikeda, Ibaraki (JP)

(73) Assignee: JX NIPPON MINING & METALS CORPORATION, Tokyo (JP)

(21) Appl. No.: 13/881,117

(22) PCT Filed: Dec. 19, 2011
(86) PCT No.: PCT/JP2011/079321

§ 371 Date: Apr. 23, 2013

(30) Foreign Application Priority Data
Dec. 22, 2010 (JP) 2010-285905

(51) Int. Cl. C23C 14/14; C23C 14/08

(52) U.S. Cl. CPC C23C 14/14; C23C 14/08
USPC 204/298.13

(57) ABSTRACT

Provided is a ferromagnetic sputtering target having a metal composition comprising 20 mol % or less of Cr, 5 mol % or more of Pt, and the balance of Co, wherein the target includes a metal base (A) and two different phases (B) and (C) in the metal base (A), the phase (B) being a Co—Ru alloy phase containing 30 mol % or more of Ru, and the phase (C) being a metal or alloy phase primarily composed of Co or a Co alloy. The present invention improves the leakage magnetic flux to provide a ferromagnetic sputtering target that can perform stable discharge with a magnetron sputtering device.

### BACKGROUND

The present invention relates to a ferromagnetic sputtering target that is used for forming a magnetic material thin film of a magnetic recording medium, in particular, a magnetic recording layer of a hard disk employing a perpendicular magnetic recording system, and relates to a nonmagnetic material particle-dispersed ferromagnetic sputtering target that provides a large leakage magnetic flux and can provide stable electric discharge in sputtering with a magnetron sputtering device.

In the field of magnetic recording represented by hard disk drives, ferromagnetic metal materials, i.e., Co, Fe, or Ni-based materials are used as materials of magnetic thin films that perform recording. For example, in recording layers of hard disks employing a longitudinal magnetic recording system, Co—Cr or Co—Cr—Pt ferromagnetic alloys of which main components are Co are used.

In recording layers of hard disks employing a perpendicular magnetic recording system that has been recently applied to practical use, composite materials each composed of a Co—Cr—Pt ferromagnetic alloy of which main component is Co and a nonmagnetic inorganic material are widely used.

In many cases, the magnetic thin film of a magnetic recording medium such as a hard disk is produced by sputtering a ferromagnetic sputtering target of which main component is the above-mentioned material for its high productivity.

Such a ferromagnetic sputtering target can be produced by a melting process or a powder metallurgical process. Though which process is used depends on the requirement in characteristics, the sputtering target composed of a ferromagnetic alloy and nonmagnetic inorganic particles, which is used in production of a recording layer of a hard disk of a perpendicular magnetic recording system, is generally produced by a powder metallurgical process. This is because inorganic material particles need to be uniformly dispersed in an alloy base, which is difficult to produce the sputtering target by a melting process.

For example, proposed is a method of preparing a sputtering target for magnetic recording media by mechanically alloying an alloy powder having an alloy phase produced by rapid solidification and a powder constituting a ceramic phase, uniformly dispersing the powder constituting a ceramic phase in the alloy powder, and molding the dispersion with a hot press (Patent Literature 1).

The target structure in this case appears such that the base links in a soft cod roe-like manner and SiO₂ (ceramics) surrounds the base (FIG. 2 of Patent Literature 1) or is dispersed in the form of strings in the base (FIG. 3 of Patent Literature 1). Though other drawings are unclear, they look like as though they show similar structures.

Unfortunately, such a structure has problems described below and is not a preferred sputtering target for magnetic recording media. Note that the spherical material shown in FIG. 4 of Patent Literature 1 is not a structure constituting the target but a mechanically alloyed powder.

A ferromagnetic sputtering target also can be produced, without using an alloy powder produced by rapid solidification, by weighing commercially available raw material powders as the components constituting a target so as to give a desired composition, mixing the powders by a known process with a ball mill and the like, and molding and sintering the powder mixture with a hot press.

For example, proposed is a method of preparing a sputtering target for magnetic recording media by mixing a powder mixture prepared by mixing a Co powder, a Cr powder, a TiO₂ powder, and a SiO₂ powder with a Co spherical powder with a planetary screw mixer and molding the resulting powder mixture with a hot press (Patent Literature 2).

The target structure in this case appears such that a phase (B) of a spherical metal is present in a metal base phase (A) in which inorganic particles are uniformly dispersed (FIG. 1 of Patent Literature 2). In such a structure, the leakage magnetic flux is not sufficiently increased in some cases depending on the contents of the constituent elements such as Co and Cr. Thus, the target structure is not a satisfactory sputtering target for magnetic recording media.

Furthermore, proposed is a method of preparing a sputtering target for magnetic recording medium thin films by mixing a Co—Cr binary alloy powder, a Pt powder, and a SiO₂ powder and hot-pressing the resulting powder mixture (Patent Literature 3).

It is described that the target structure in this case has a Pt phase, a SiO₂ phase, and a Co—Cr binary alloy phase and that a dispersion layer is observed in the periphery of the Co—Cr binary alloy layer (not shown in drawing). Such a structure is also not a satisfactory sputtering target for magnetic recording media.

There are sputtering devices of various systems. In formation of the above-described magnetic recording films, magnetron sputtering devices equipped with DC power sources are widely used for their high productivity. Sputtering is a method of generating an electric field by applying a high voltage between a substrate serving as a positive electrode and a target serving as a negative electrode disposed so as to face each other under an inert gas atmosphere.

On this occasion, the inert gas is ionized into plasma composed of electrons and cations. The cations in the plasma collide with the surface of the target (negative electrode) to make the atoms constituting the target to fly out from the target and to allow the atoms to adhere to the facing substrate surface to form a film. Sputtering is based on the principle that a film of the material constituting a target is formed on a substrate by such a series of actions.
Patent Literature 1: Japanese Patent Laid-Open Publication No. H10-88333
Patent Literature 2: Japanese Patent Application No. 2010-011326
Patent Literature 3: Japanese Patent Laid-Open Publication No. 2009-1860

### SUMMARY OF THE INVENTION

### Technical Problem

In general, in sputtering of a ferromagnetic sputtering target with a magnetron sputtering device, most of the magnetic flux from a magnet passes through the inside of target made of a ferromagnetic material to reduce the leakage magnetic flux, resulting in a big problem of no discharge or unstable discharge in sputtering.

In order to solve this problem, a reduction in content ratio of Co, which is a ferromagnetic metal, is suggested. A reduction in Co content, however, does not allow formation of a desired magnetic recording film and is therefore not an essential solution. Though it is possible to increase the leakage magnetic flux by reducing the thickness of the target, in this case, the target lifetime is shortened to require frequent replacement of the target, which causes an increase in the cost.

In view of the problems mentioned above, it is an object of the present invention to provide a nonmagnetic material particle-dispersed ferromagnetic sputtering target that increases the leakage magnetic flux to allow stable discharge with a magnetron sputtering device.

### Solution To Problem

In order to solve the above-mentioned problems, the present inventors have performed diligent studies and, as a result, have found that a target providing a large leakage magnetic flux can be obtained by regulating the composition and structural constitution of the target.

Accordingly, based on the findings, the present invention provides:

1) a ferromagnetic sputtering target having a metal composition comprising 20 mol % or less of Cr, 0.5 mol % or more and 30 mol % or less of Ru, and the balance of Co, wherein the target includes a metal base (A) and two different phases (B) and (C) in the metal base (A), the phase (B) being a Co—Ru alloy phase containing 30 mol % or more of Ru, and the phase (C) being a metal or alloy phase primarily composed of Co or a Co alloy.

The present invention further provides:

2) a ferromagnetic sputtering target having a metal composition comprising 20 mol % or less of Cr, 0.5 mol % or more and 30 mol % or less of Ru, 0.5 mol % or more of Pt, and the balance of Co, wherein the target structure includes a metal base (A) and two different phases (B) and (C) in the metal base (A), wherein the phase (B) being a Co—Ru alloy phase containing 30 mol % or more of Ru, and the phase (C) being a metal or alloy phase primarily composed of Co or a Co alloy.

The present invention further provides:

3) the ferromagnetic sputtering target according to 1) or 2) above, wherein the metal or alloy phase (C) contains 90 mol % or more of Co.

The present invention further provides:

4) the ferromagnetic sputtering target according to any one of 1) or 3) above, further comprising 0.5 mol % or more and 10 mol % or less of at least one element selected from B, Ti, V, Mn, Zr, Nb, Ru, Mo, Ta, W, Si, and Al as additional element.

The present invention further provides:

5) the ferromagnetic sputtering target according to any one of 1) to 4) above, wherein the metal base (A) contains at least one inorganic material selected from carbon, oxides, nitrides, carbides, and carbonitrides in the metal base.

The present invention further provides:

6) the ferromagnetic sputtering target according to any one of 1) to 5) above, wherein the inorganic material is at least one oxide of element selected from Cr, Ta, Si, Ti, Zr, Al, Nb, B, and Co; and the volume proportion of the nonmagnetic material is 20 to 40%.

The present invention further provides:

7) the ferromagnetic sputtering target according to any one of 1) to 6) above, having a relative density of 97% or more.

The obtained nonmagnetic material particle-dispersed ferromagnetic sputtering target of the present invention provides a large leakage magnetic flux to efficiently facilitate ionization of an inert gas to give stable discharge when the target is used in a magnetron sputtering device. It is possible to increase the thickness of the target to enable a reduction in frequency of replacement of the target, resulting in an advantage that a magnetic material thin film can be produced at a low cost.

### DETAILED DESCRIPTION OF THE INVENTION

The main component constituting a ferromagnetic sputtering target of the present invention is a metal composition comprising 20 mol % or less of Cr, 0.5 mol % or more and 30 mol % or less of Ru, and the balance of Co; or a metal composition comprising 20 mol % or less of Cr, 0.5 mol % or more and 30 mol % or less of Ru, 0.5 mol % or more of Pt, and the balance of Co.

Cr is an indispensable component, and the content is, therefore, higher than 0 mol %. That is, the Cr content is higher than the analyzable lower limit. Furthermore, as long as the Cr content is not higher than 20 mol %, the effects can be obtained even if the amount of Cr is small.

When the Ru content is 0.5 mol % or more, the effects of a magnetic material thin film can be obtained. Thus, the lower limit is determined to be 0.5 mol %. In contrast, the upper limit is determined to be 30 mol % since a too large amount of Ru is unfavorable because of its characteristics as a magnetic material.

The amount of Pt is desirably 45 mol % or less. An excessive amount of Pt decreases the characteristics as a magnetic material, and Pt is expensive. Accordingly, a smaller amount of Pt is desirable from the viewpoint of manufacturing cost.

The ferromagnetic sputtering target can further contain 0.5 mol % or more and 10 mol % or less of at least one element selected from B, Ti, V, Mn, Zr, Nb, Ru, Mo, Ta, W, Si, and Al, as additional element. These elements are optionally added to the target for improving the characteristics as a magnetic recording medium. The blending ratios can be variously varied within the above-mentioned ranges, while maintaining the characteristics as an effective magnetic recording medium.

The 0.5 mol % or more and 10 mol % or less of at least one element selected from B, Ti, V, Mn, Zr, Nb, Ru, Mo, Ta, W, Si, and Al, as additional element, which is basically present in the metal base (A), may slightly disperse into the phase (B) of a Co—Ru alloy described below through the interface with the phase (B). Such a case is encompassed in the present invention.

Similarly, the 0.5 mol % or more and 10 mol % or less of at least one element selected from B, Ti, V, Mn, Zr, Nb, Ru, Mo, Ta, W, Si, and Al, as additional element, which is basically present in the metal base (A), may slightly disperse into the metal or alloy phase (C) containing Co or a Co alloy as the main component described below through the interface with the phase (C). Such a case is encompassed in the present invention.

Furthermore, the metal or alloy phase (C) may contain 90 mol % or more of Co and at least one alloy with element selected from B, Ti, V, Mn, Zr, Nb, Ru, Mo, Ta, W, Si, and Al, as additional element.

An important point of the present invention is that the structure of the target comprises a metal base (A), and a phase (B) of Co—Ru alloy containing 30 mol % or more of Ru and a phase (C) of a metal or alloy primarily composed of Co or a Co alloy, both in the metal base (A). The phase (B) has a maximum magnetic permeability lower than that of the structure surrounding the phase, and the phases separated from each other by the metal base (A). The phase (C) has a maximum magnetic permeability higher than that of the structure surrounding the phase, and the phases separated from each other by the metal base (A).

Though the effect of improving the leakage magnetic flux is expressed even in a target structure composed of a metal base (A) and a Co—Ru alloy phase (B) containing 30 mol % or more of Ru or a target composed of a metal base (A) and a metal or alloy phase (C) primarily composed of Co or a Co alloy, the effect of improving the leakage magnetic flux is further enhanced in a target including the metal base (A), the phase (B), and the phase (C).

The reasons of the improvement in leakage magnetic flux in the target having such a structure are not necessarily obvious at the present moment, however, it is believed that the structure generates a high magnetic flux density portion as well as a low magnetic flux density portion inside the target to make magnetostatic energy high compared with that in the structure having a uniform magnetic permeability and that the leakage of the magnetic flux to the outside of the target is energetically advantageous.

The phase (B) desirably has a diameter of 10 to 150 μm. The phase (B) and fine inorganic material particles are present in the metal base (A). If the diameter of the phase (B) is smaller than 10 μm, the difference in size with the inorganic material particles is small to facilitate diffusion between the phase (B) and the metal base (A) during sintering of the target material.

The difference in structural component between the metal base (A) and the phase (B) tends to become unclear with the progress of the diffusion. Thus, the diameter of the phase (B) is desirably 10 μm or more and preferably 30 μm or more.

Meanwhile, if the diameter exceeds 150 μm, the smoothness of the target surface is lost with the progress of sputtering. This may readily cause a problem of particles. Thus, the diameter of the phase (B) is desirably 150 μm or less.

All of these regulations are for increasing the leakage magnetic flux. The leakage magnetic flux also can be controlled by the amounts and types of additional metals and inorganic material particles contained in the target. Accordingly, the above-described size of the phase (B) does not necessarily have to be satisfied, but obviously, is one of favorable conditions.

Even if the volume proportion of the phase (B) to the total volume of the target or the area proportion of the phase (B) to the erosion surface of the target is small (e.g., about 1%), the effect of a certain level can be obtained.

In order to sufficiently obtain the effect by the presence of the phase (B), the volume proportion of the phase (B) to the total volume of the target or the area proportion of the phase (B) to the erosion surface of the target is desirably 10% or more. A larger volume of the phase (B) can increase the leakage magnetic flux.

The volume proportion of the phase (B) to the total volume of the target or the area proportion of the phase (B) to the erosion surface of the target can be 50% or more, further 60% or more, in some target compositions. The volume or area proportion can be appropriately adjusted depending on the composition of the target. Such a case is encompassed in the present invention.

The phase (B) in the present invention may have any shape, and the average particle diameter means the average between the minimum diameter and the maximum diameter.

The composition of the phase (B) is different from that of the metal base (A). Therefore, the composition in the periphery of the phase (B) may slightly change from that of the phase (B) by diffusion of elements during sintering.

In the range of a phase having a shape similar to that of the phase (B) and having diameters (major axis and minor axis) each reduced to two-thirds that of the phase (B), the purpose can be achieved as long as the phase (B) is made of a Co—Ru alloy containing 30 mol % or more of Ru. The present invention encompasses such a case, and the purpose of the present invention can be achieved under such conditions.

The phase (C) desirably has a diameter of 30 to 150 μm. If the diameter of the phase (C) is smaller than 30 μm, the difference in particle size with the metals mixed with the inorganic material particles is small to facilitate diffusion between the phase (C) and the metal base (A) during sintering of the target material. Thus, the difference in structural component between the metal base (A) and the phase (C) tends to become unclear. Accordingly, the diameter of the phase (C) is desirably 30 μm or more and preferably 40 μm or more.

Meanwhile, if the diameter exceeds 150 μm, the smoothness of the target surface decreases with the progress of sputtering. This may readily cause a problem of particles. Thus, the size of the phase (C) is desirably 30 to 150 μm.

All of these regulations are for increasing the leakage magnetic flux. The leakage magnetic flux also can be controlled by the amounts and types of additional metals and inorganic material particles contained in the target. Accordingly, the above-described size of the phase (C) does not necessarily have to be satisfied, but obviously, is one of favorable conditions.

In order to sufficiently obtain the effect by the presence of the phase (C), the volume proportion of the phase (C) to the total volume of the target or the area proportion of the phase (C) to the erosion surface of the target is desirably 10% or more. A larger volume of the phase (C) can increase the leakage magnetic flux.

The volume proportion of the phase (C) to the total volume of the target or the area proportion of the phase (C) to the erosion surface of the target can be 50% or more, further 60% or more, in some target compositions. The volume or area proportion can be appropriately adjusted depending on the composition of the target. Such a case is encompassed in the present invention.

The phase (C) in the present invention may have any shape, and the average particle diameter means the average of the minimum diameter and the maximum diameter.

Therefore, the composition in the periphery of the phase (C) may slightly change from that of the phase (C) by diffusion of elements during sintering.

In the range of a phase having a shape similar to that of the phase (C) and having diameters (major axis and minor axis) each reduced to two-thirds that of the phase (C), the purpose can be achieved as long as the main component of the metal or alloy phase (C) is Co or a Co alloy. The present invention encompasses such a case, and the purpose of the present invention can be achieved under such conditions.

Furthermore, the ferromagnetic sputtering target of the present invention may contain at least one inorganic material selected from carbon, oxides, nitrides, carbides, and carbonitrides in a state dispersed in the metal base. In such a case, the target has characteristics suitable as a material for a magnetic recording film having a granular structure, in particular, a recording film for a hard disk drive employing a perpendicular magnetic recording system.

As the inorganic material, at least one oxide of element selected from Cr, Ta, Si, Ti, Zr, Al, Nb, B, and Co is effective. The volume proportion of the nonmagnetic material can be 20 to 40%. In the case of an oxide of Cr, the amount of Cr of the oxide is distinguished from the amount of Cr added as a metal and is determined as a volume proportion as a chromium oxide.

Though the nonmagnetic material particles are usually dispersed in the metal base (A), some of the nonmagnetic material particles adhere to the circumference of the phase (B) or the phase (C) or are contained inside the phase (B) or the phase (C) during production of a target. The nonmagnetic material particles in such a case, if the amount is small, do not affect the magnetic characteristics of the phase (B) or the phase (C) and do not inhibit the purpose.

The ferromagnetic sputtering target of the present invention more desirably has a relative density of 97% or more. It is generally known that a target having a higher density can more effectively reduce the amount of particles occurring during sputtering. In the present invention also, similarly, a higher density is preferred. In the present invention, a relative density of 97% or more can be achieved.

The relative density in the present invention is a value determined by dividing the measured density of a target by the calculated density (theoretical density). The calculated density is a density when it is assumed that the structural components of a target are mixed without diffusing to or reacting with each other and is calculated by the following expression:

Formula: calculated density=Σ[(molecular weight of a structural component)×(molar ratio of the structural component)]/Σ[(molecular weight of the structural component)×(molar ratio of the structural component)/(literature density data of the structural component)],

Here, Σ is the sum of the values of all structural components of the target.

The obtained target provides a large leakage magnetic flux. When the target is used in a magnetron sputtering device, ionization of an inert gas is efficiently facilitated to give stable discharge. It is possible to increase the thickness of the target to enable a reduction in frequency of replacement of the target, resulting in an advantage that a magnetic material thin film can be produced at a low cost.

Furthermore, the increase in density has an advantage of reducing the occurrence amount of particles that cause a reduction in yield.

The ferromagnetic sputtering target of the present invention can be produced by a powder metallurgy process. First, a powder of a metal element or alloy, and an optional powder of an additional metal element are prepared. Here, note that a Co—Ru alloy powder is indispensable for forming the phase (B) as a metal element or alloy. Though each metal element powder may be produced by any method, the maximum particle diameters of these powders are desirably 20 μm or less each.

Instead of each metal element powder, powders of alloys of these metals may be prepared. In such a case also, though the powders may be produced by any method, the maximum particle diameters of these powders are desirably 20 μm or less each. Meanwhile, since too small a particle diameter facilitates oxidation to cause problems such as a deviation of the component composition from the necessary range, the diameter is further desirably 0.1 μm or more.

Subsequently, the metal powder and the alloy powder are weighed to give a desirable composition and are mixed and pulverized with a known procedure using such as a ball mill. When an inorganic material powder is also added, the powder may be mixed with the metal powder and the alloy powder in this stage.

As the inorganic material powder, a carbon powder, an oxide powder, a nitride powder, a carbide powder, or a carbonitride powder is prepared. The inorganic material powder desirably has a maximum particle diameter of 5 μm or less. Meanwhile, since too small a particle diameter tends to cause aggregation, the diameter is further desirably 0.1 μm or more.

The Co—Ru powder can be prepared by sintering a powder mixture of a Co powder and a Ru powder and pulverizing and sieving the sintered product. The pulverization is desirably performed with a high energy ball mill. The obtained Co—Ru powder having a diameter in a range of 30 to 150 μm is mixed with a metal powder prepared in advance and an optionally selected inorganic material powder with a mixer.

The mixer is preferably a planetary screw mixer or planetary screw agitator. In addition, considering the problem of oxidation during mixing, the mixing is preferably performed in an inert gas atmosphere or in vacuum.

The high energy ball mill can pulverize and mix raw material powders within a short time compared with a ball mill or a vibration mill. A Co powder having a diameter in a range of 30 to 150 μm can be prepared by gas atomization and sieving of the product.

The obtained powder is molded and sintered with a vacuum hot press device, followed by machining into a desired shape to provide a ferromagnetic sputtering target of the present invention.

The molding and sintering is not limited to hot pressing and may be performed by plasma discharge sintering or hot hydrostatic pressure sintering.

The retention temperature for the sintering is preferably set to the lowest in the temperature range in which the target is sufficiently densified. Though it depends on the composition of a target, in many cases, the temperature is in the range of 800 to 1300° C. The pressure in the sintering is preferably 300 to 500 kg/cm².

### EXAMPLES

The present invention will now be described by Examples and Comparative Examples. The Examples are merely illustrative, and the present invention shall in no way be limited thereby. In other words, the present invention shall only be limited by the scope of claim for a patent, and shall include various modifications other than the Examples of this invention.

### Example 1 And Comparative Examples 1 To 3

In Example 1, a Co powder having an average particle diameter of 3 μm, a Cr powder having an average particle diameter of 6 μm, a CoO powder having an average particle diameter of 2 μm, a SiO₂ powder having an average particle diameter of 1 μm, a Co-45Ru (mol %) powder having a diameter in the range of 50 to 150 μm, and a Co powder having a diameter in the range of 70 to 150 μm were prepared as raw material powders.

These powders were weighed at weight proportions of 18.70 wt % of the Co powder, 3.52 wt % of the Cr powder, 5.76 wt % of the CoO powder, 6.46 wt % of the SiO₂ powder, 45.56 wt % of the Co—Ru powder, and 20.0 wt % of the Co powder having a diameter in the range of 70 to 150 μm to give a target composition of 88(80Co-5Cr-15Ru)-5CoO-7SiO₂ (mol %).

Subsequently, the Co powder, the Cr powder, the CoO powder, the SiO₂ powder, and the Co powder having a diameter in the range of 70 to 150 μm were charged in a 10-liter ball mill pot together with zirconia balls as a pulverizing medium, and the mill pot was sealed and rotated for 20 hours for mixing. The resulting powder mixture was further mixed with the Co—Ru powder with a planetary screw mixer having a ball capacity of about 7 liters for 10 minutes.

The resulting powder mixture was charged in a carbon mold and was hot-pressed in a vacuum atmosphere under conditions of a temperature of 1100° C., a retention time of 2 hours, and a pressure of 30 MPa to give a sintered compact. The sintered compact was ground with a surface grinder to give a disk-shaped target having a diameter of 180 mm and a thickness of 5 mm.

The leakage magnetic flux was measured with reference to ASTM F2086-01 (Standard Test Method for Pass Through Flux of Circular Magnetic Sputtering Targets, Method 2). The target was fixed at the center thereof and was rotated by 0, 30, 60, 90, and 120 degrees, and the leakage magnetic flux density (PTF) of the target was measured at each degree of rotation and was divided by the reference field value defined in ASTM and multiplied by 100 to give a percentage value. The average leakage magnetic flux density (PTF (%)) obtained as the average of the values at the five points was 52.0%.

In Comparative Example 1, as raw material powders, a Co powder having an average particle diameter of 3 μm, a Cr powder having an average particle diameter of 6 μm, a Ru powder having an average particle diameter of 10 μm, a CoO powder having an average particle diameter of 2 μm, and a SiO₂ powder having an average particle diameter of 1 μm were weighed at weight proportions of 63.76 wt % of the Co powder, 3.52 wt % of the Cr powder, 20.50 wt % of the Ru powder, 5.76 wt % of the CoO powder, and 6.46 wt % of the SiO₂ powder to give a target composition of 88(80Co-5Cr-15Ru)-5CoO-7SiO₂ (mol %).

These powders were charged in a 10-liter ball mill pot together with zirconia balls as a pulverizing medium, and the mill pot was sealed and rotated for 20 hours for mixing.

Subsequently, the resulting powder mixture was charged in a carbon mold and was hot-pressed in a vacuum atmosphere under conditions of a temperature of 1100° C., a retention time of 2 hours, and a pressure of 30 MPa to give a sintered compact. The sintered compact was ground with a surface grinder to give a disk-shaped target having a diameter of 180 mm and a thickness of 5 mm. The average leakage magnetic flux density (PTF) of the target was measured to be 43.5%.

In Comparative Example 2, a Co powder having an average particle diameter of 3 μm, a Cr powder having an average particle diameter of 6 μm, a CoO powder having an average particle diameter of 2 μm, a SiO₂ powder having an average particle diameter of 1 μm, and a Co-70Ru (mol %) powder having a diameter in the range of 50 to 150 μm were prepared as raw material powders.

These powders were weighed at weight proportions of 54.97 wt % of the Co powder, 3.52 wt % of the Cr powder, 5.76 wt % of the CoO powder, 6.46 wt % of the SiO₂ powder, and 29.29 wt % of the Co—Ru powder to give a target composition of 88(80Co-5Cr-15Ru)-5CoO-7SiO₂ (mol %).

Subsequently, the Co powder, the Cr powder, the CoO powder, and the SiO₂ powder were charged in a 10-liter ball mill pot together with zirconia balls as a pulverizing medium, and the mill pot was sealed and rotated for 20 hours for mixing. The resulting powder mixture was further mixed with the Co—Ru powder with a planetary screw mixer having a ball capacity of about 7 liters for 10 minutes.

The resulting powder mixture was charged in a carbon mold and was hot-pressed in a vacuum atmosphere under conditions of a temperature of 1100° C., a retention time of 2 hours, and a pressure of 30 MPa to give a sintered compact. The sintered compact was ground with a surface grinder to give a disk-shaped target having a diameter of 180 mm and a thickness of 5 mm. The average leakage magnetic flux density (PTF) of the target was measured to be 44.9%.

In Comparative Example 3, a Co powder having an average particle diameter of 3 μm, a Cr powder having an average particle diameter of 6 μm, a CoO powder having an average particle diameter of 2 μm, a SiO₂ powder having an average particle diameter of 1 μm, and a Co-36Ru (mol %) powder having a diameter in the range of 50 to 150 μm were prepared as raw material powders.

These powders were weighed at weight proportions of 27.31 wt % of the Co powder, 3.52 wt % of the Cr powder, 5.76 wt % of the CoO powder, 6.46 wt % of the SiO₂ powder, and 56.95 wt % of the Co—Ru powder to give a target composition of 88(80Co-5Cr-15Ru)-5CoO-7SiO₂ (mol %).

Subsequently, the Co powder, the Cr powder, the CoO powder, and the SiO₂ powder were charged in a 10-liter ball mill pot together with zirconia balls as a pulverizing medium, and the mill pot was sealed and rotated for 20 hours for mixing. The resulting powder mixture was further mixed with the Co—Ru powder with a planetary screw mixer having a ball capacity of about 7 liters for 10 minutes.

The resulting powder mixture was charged in a carbon mold and was hot-pressed in a vacuum atmosphere under conditions of a temperature of 1100° C., a retention time of 2 hours, and a pressure of 30 MPa to give a sintered compact. The sintered compact was ground with a surface grinder to give a disk-shaped target having a diameter of 180 mm and a thickness of 5 mm. The average leakage magnetic flux density (PTF) of the target was measured to be 46.2%.

The results in the above are collectively shown in Table 1.

TABLE 1

| | Composition | | | | Relative |
|---|---|---|---|---|---|
| | of target | | | | density |
| No. | (mol %) | Phase (B) | Phase (C) | PTF (%) | (%) |
| Example 1 | 88(80Co—5Cr—15Ru)—5CoO—7SiO₂ | Particle diameter: | Particle diameter: | 52.0 | 97.4 |
| | | 50 to 150 μm, | 70 to 150 μm, | | |
| | | Co—45 mol % Ru | pure Co | | |
| Comparative | 88(80Co—5Cr—15Ru)—5CoO—7SiO₂ | None | None | 43.5 | 97.0 |
| Example 1 | | | | | |
| Comparative | 88(80Co—5Cr—15Ru)—5CoO—7SiO₂ | Particle diameter: | None | 44.9 | 97.2 |
| Example 2 | | 50 to 150 μm, | | | |
| | | Co—70 mol % Ru | | | |
| Comparative | 88(80Co—5Cr—15Ru)—5CoO—7SiO₂ | Particle diameter: | None | 46.2 | 97.4 |
| Example 3 | | 50 to 150 μm, | | | |
| | | Co—36 mol % Ru | | | |

As shown in Table 1, the average leakage magnetic flux density (PTF) of the target in Example 1 was 52.0% and was confirmed to be considerably improved compared with 43.5%, 44.9%, and 46.2%, in Comparative Examples 1 to 3, respectively. In Example 1, the relative density was 97.4%. Thus, a target having a high density of exceeding 97% was provided.

Though the above-described Example shows an example of a target composition of 88(80Co-5Cr-15Ru)-5CoO-7SiO₂ (mol %), it was confirmed that similar effects can be obtained even if the composition ratio is changed within the range of the present invention.

Though, in the above-described Examples, Ru alone is added to the target, the target may contain at least one element selected from B, Ti, V, Mn, Zr, Nb, Ru, Mo, Ta, W, Si, and Al, as additional element, and all of such targets can maintain the characteristics as effective magnetic recording media. In other words, these elements are optionally added to targets for improving the characteristics as magnetic recording media. Though the effects are not specially shown in examples, it was confirmed that the effects were equivalent to those shown in the Example of the present invention.

Though the above-described Example shows a case of oxides of Co and Si, other oxides of Cr, Ta, Ti, Zr, Al, Nb, or B show equivalent effects. In addition, though the Example shows a case of using oxides, it was confirmed that nitrides, carbides, and carbonitrides of these elements and further carbon can show effects equivalent to those of oxides.

The present invention can notably improve the leakage magnetic flux by regulating the structural constitution of a ferromagnetic sputtering target. With the use of a target of the present invention, stable discharge in sputtering with a magnetron sputtering device can be achieved. Furthermore, it is possible to increase the thickness of a target, and thereby the target lifetime becomes long to allow production of a magnetic material thin film at a low cost.

The target of the present invention is useful as a ferromagnetic sputtering target that is used for forming a magnetic material thin film of a magnetic recording medium, in particular, forming a film of a hard disk drive recording layer.

1. A ferromagnetic sputtering target having a metal composition comprising 20 mol % or less of Cr, 0.5 mol % or more and 30 mol % or less of Ru, and the balance of Co, wherein the target includes a metal base (A) and two different phases (B) and (C) in the metal base (A), the phase (B) being a Co—Ru alloy phase containing 30 mol % or more of Ru, and the phase (C) being a metal or alloy phase primarily composed of Co or a Co alloy.

2. A ferromagnetic sputtering target having a metal composition comprising 20 mol % or less of Cr, 0.5 mol % or more and 30 mol % or less of Ru, 0.5 mol % or more of Pt, and the balance of Co, wherein the target structure includes a metal base (A) and two different phases (B) and (C) in the metal base (A), the phase (B) being a Co—Ru alloy phase containing 30 mol % or more of Ru, and the phase (C) being a metal or alloy phase primarily composed of Co or a Co alloy.

3. The ferromagnetic sputtering target according to claim 2, wherein the metal or alloy phase (C) contains 90 mol % or more of Co.

4. The ferromagnetic sputtering target according to claim 3, further comprising 0.5 mol % or more and 10 mol % or less of at least one element selected from the group consisting of B, Ti, V, Mn, Zr, Nb, Ru, Mo, Ta, W, Si, and Al.

5. The ferromagnetic sputtering target according to claim 4, wherein the metal base (A) contains at least one inorganic material selected from the group consisting of carbon, oxides, nitrides, carbides, and carbonitrides in the metal base.

6. The ferromagnetic sputtering target according to claim 5, wherein the at least one inorganic material is at least one oxide of an element selected from the group consisting of Cr, Ta, Si, Ti, Zr, Al, Nb, B, and Co; and the a volume proportion of the nonmagnetic material composed of the at least one inorganic material is 20 to 40%.

7. The ferromagnetic sputtering target according to claim 6, having wherein the sputtering target has a relative density of 97% or more.

8. The ferromagnetic sputtering target according to claim 2, further comprising 0.5 to 10 mol % of at least one element selected from the group consisting of B, Ti, V, Mn, Zr, Nb, Ru, Mo, Ta, W, Si, and Al.

9. The ferromagnetic sputtering target according to claim 2, wherein the metal base (A) contains at least one inorganic material selected from the group consisting of carbon, oxides, nitrides, carbides, and carbonitrides in the metal base.

10. The ferromagnetic sputtering target according to claim 9, wherein the at least one inorganic material is at least one oxide of an element selected from the group consisting of Cr, Ta, Si, Ti, Zr, Al, Nb, B, and Co, and wherein a volume proportion of nonmagnetic material composed of the at least one inorganic material is 20 to 40%.

11. The ferromagnetic sputtering target according to claim 2, wherein the sputtering target has a relative density of 97% or more.

12. The ferromagnetic sputtering target according to claim 1, wherein the metal or alloy phase (C) contains 90 mol % or more of Co.

13. The ferromagnetic sputtering target according to claim 12, further comprising 0.5 to 10 mol % of at least one element selected from the group consisting of B, Ti, V, Mn, Zr, Nb, Ru, Mo, Ta, W, Si, and Al.

14. The ferromagnetic sputtering target according to claim 13, wherein the metal base (A) contains at least one inorganic material selected from the group consisting of carbon, oxides, nitrides, carbides, and carbonitrides in the metal base.

15. The ferromagnetic sputtering target according to claim 14, wherein the at least one inorganic material is at least one oxide of an element selected from the group consisting of Cr, Ta, Si, Ti, Zr, Al, Nb, B, and Co, and wherein a volume proportion of nonmagnetic material composed of the at least one inorganic material is 20 to 40%.

16. The ferromagnetic sputtering target according to claim 15, wherein the sputtering target has a relative density of 97% or more.

17. The ferromagnetic sputtering target according to claim 1, further comprising 0.5 to 10 mol % of at least one element selected from the group consisting of B, Ti, V, Mn, Zr, Nb, Ru, Mo, Ta, W, Si, and Al.

18. The ferromagnetic sputtering target according to claim 1, wherein the metal base (A) contains at least one inorganic material selected from the group consisting of carbon, oxides, nitrides, carbides, and carbonitrides in the metal base.

19. The ferromagnetic sputtering target according to claim 18, wherein the at least one inorganic material is at least one oxide of an element selected from the group consisting of Cr, Ta, Si, Ti, Zr, Al, Nb, B, and Co, and wherein a volume proportion of nonmagnetic material composed of the at least one inorganic material is 20 to 40%.

20. The ferromagnetic sputtering target according to claim 1, wherein the sputtering target has a relative density of 97% or more.
